(19) United States
(12) Patent Application Publication
(10) Pub. No.: US 2026/0372022 A1
(43) Pub. Date: Nov. 19, 2026

(54) REPAIR PRIORITIZATION OF INTEGRATED CIRCUITS

(71) Applicant: INTERNATIONAL BUSINESS MACHINES CORPORATION, Armonk, NY (US)

(72) Inventors: Uma Srinivasan, Poughkeepsie, NY (US); William V. Huott, Holmes, NY (US); Austen Hall, Portland, ME (US); Brian Noble, Lagrangeville, NY (US); Jose Martinez, St. Albans, VT (US)

(21) Appl. No.: 19/208,769

(22) Filed: May 15, 2025

(51) Int. Cl. H10P 74/00

(52) U.S. Cl. CPC H10P 74/277

(57) ABSTRACT

An integrated circuit is repaired. The repairing includes selecting a set of test-repairs of a plurality of sets of test-repairs generated to test the integrated circuit. The plurality of sets of test-repairs is assigned one or more priorities based on one or more predefined criteria related to the integrated circuit. The selecting is based on a chosen priority. One or more tests are executed on the integrated circuit and a number of repairs to be performed is determined, based on the executing of the one or more tests of the set of test-repairs. It is evaluated whether the number of repairs to be performed is outside one or more architectural limits assigned to the integrated circuit. Processing to perform selective repairs on the integrated circuit is performed based on the evaluating indicating the number of repairs is outside the one or more architectural limits.

### BACKGROUND

One or more aspects relate, in general, to integrated circuits, and in particular, to testing and repairing integrated circuits.

Integrated circuits are composed of electronic circuits used to provide various functions. One function provided by an integrated circuit is memory. As examples, the integrated circuit may be a memory array, or an integrated circuit may include one or more memory arrays. A memory array is a structural arrangement of memory cells used to provide memory. Each memory cell is an electronic circuit that stores one bit of binary data.

A memory array is an example of a repairable circuit and typically includes one or more spare elements (e.g., memory cells) to be used to repair the memory array should a repair be necessary. Spare elements in the memory array contribute to memory yield, the percentage of functional memory. An increase in the number of spare elements increases the memory yield. However, there is a limit to how much redundancy is allowed without sacrificing area and power.

### SUMMARY

Shortcomings of the prior art are overcome, and additional advantages are provided through the provision of a method. The method includes repairing an integrated circuit. The repairing includes selecting a set of test-repairs of a plurality of sets of test-repairs generated to test the integrated circuit. The plurality of sets of test-repairs being assigned one or more priorities based on one or more predefined criteria related to the integrated circuit. The selecting is based on a chosen priority of the one or more priorities, in which the set of test-repairs selected has the chosen priority. One or more tests of the set of test-repairs are executed on the integrated circuit and a number of repairs of the set of test-repairs to be performed on the integrated circuit is determined, based on the executing of the one or more tests of the set of test-repairs. It is evaluated whether the number of repairs to be performed is outside one or more architectural limits assigned to the integrated circuit. Processing to perform selective repairs on the integrated circuit is performed based on the evaluating indicating the number of repairs is outside the one or more architectural limits assigned to the integrated circuit.

In one or more aspects, a method is provided that includes repairing an integrated circuit. The integrated circuit is assigned an integrated circuit repair limit and includes a plurality of memory arrays. The plurality of memory arrays is assigned one or more array repair limits. The repairing includes selecting a set of test-repairs of a plurality of sets of test-repairs generated to test the integrated circuit. The plurality of sets of test-repairs is assigned one or more priorities based on one or more predefined criteria related to the integrated circuit. The selecting is based on a chosen priority of the one or more priorities, in which the set of test-repairs selected has the chosen priority. One or more tests of the set of test-repairs are executed on a memory array of the plurality of memory arrays of the integrated circuit. A number of repairs of the set of test-repairs to be performed on the memory array, based on the executing of the one or more tests of the set of test-repairs, is determined. It is evaluated whether the number of repairs to be performed is outside an array repair limit assigned to the memory array. It is evaluated whether the number of repairs to be performed is outside the integrated circuit repair limit assigned to the integrated circuit. Based on the number of repairs to be performed being outside the array repair limit and the integrated circuit repair limit, it is determined whether the memory array is to be downgraded to a lower priority level compared to the priority level at which it was tested. The memory array is downgraded to the lower priority level to continue repairing one or more other memory arrays of the plurality of memory arrays, based on the determining indicating that the memory array is to be downgraded, wherein the integrated circuit is still usable subsequent to the downgrading.

Integrated circuits, computer systems and computer program products relating to one or more aspects are also described and claimed herein. Further, services relating to one or more aspects are also described and may be claimed herein.

Additional features and advantages are realized through the techniques described herein. Other embodiments and aspects are described in detail herein and are considered a part of the claimed aspects.

### BRIEF DESCRIPTION OF THE DRAWINGS

One or more aspects are particularly pointed out and distinctly claimed as examples in the claims at the conclusion of the specification. The foregoing and objects, features, and advantages of one or more aspects are apparent from the following detailed description taken in conjunction with the accompanying drawings in which:

FIG. 1 depicts one example of an integrated circuit, in accordance with one or more aspects of the present disclosure;

FIG. 2 depicts one example of the test-repair prioritization logic of FIG. 1, in accordance with one or more aspects of the present disclosure;

FIG. 3 depicts one example of performing tests/repairs based on prioritization and architectural limits, in accordance with one or more aspects of the present disclosure;

FIG. 4 depicts further details of one example of performing tests/repairs based on prioritization and architectural limits, in accordance with one or more aspects of the present disclosure;

FIG. 5 depicts one example of a high priority test-repair prioritization process, in accordance with one or more aspects of the present disclosure;

FIG. 6 depicts one example of a lower priority test-repair prioritization process, in accordance with one or more aspects of the present disclosure;

FIG. 7 depicts one example of a flow diagram of a fabrication process used in semiconductor design, manufacture, and/or test, in accordance with one or more aspects of the present disclosure;

FIG. 8 depicts one example of a high-level Electronic Design Automation (EDA) tool flow, in accordance with one or more aspects of the present disclosure;

FIG. 9 depicts one example of a block diagram of an exemplary design flow, in accordance with one or more aspects of the present disclosure;

FIG. 10 depicts one example of a computing environment to incorporate, perform and/or use one or more aspects of the present disclosure; and

FIG. 11 depicts one example of a machine learning training system that may be used in accordance with one or more aspects of the present disclosure.

### DETAILED DESCRIPTION

In accordance with one or more aspects of the present disclosure, a capability is provided to facilitate and/or improve testing and/or repairing of integrated circuits (also referred to as chips). Integrated circuits provide various functions, including memory, used in devices, such as computing devices (e.g., processors, computers, etc.), mobile phones, televisions, automobiles, sensors, other electronic devices, etc.

In one or more examples, an integrated circuit may be a memory array, or an integrated circuit may include one or more memory arrays. A memory array, as mentioned herein, is an example of a repairable circuit and typically includes one or more spare elements (e.g., memory cells) to be used to repair the memory array should tests of a set of test-repairs indicate that repairs are to be made. Spare elements in the memory array contribute to memory yield, the percentage of functional memory. An increase in the number of spare elements increases the memory yield. However, there is a limit to how much redundancy is allowed without sacrificing area and power.

To repair a memory array or other repairable circuit, in one example, built-in self-tests are utilized. A built-in self-test is logic (e.g., hardware logic) added to an integrated circuit to periodically test its own operation and perform repairs if testing indicates repairs are to be made. Typically, only the patterns and tests of the built-in self-tests that are allowed to use redundant elements in an array and apply all the repairs available as indicated by the test results are allowed to be run. Typically, when the redundant elements needed exceed the available redundant elements in a memory array, the integrated circuit is rejected.

Although built-in self-tests are used in one example, other logic (e.g., coupled to but separate from the integrated circuit) may be used to perform testing and/or repairing of integrated circuits. Further, although in one example, the tests/repairs are implemented in hardware logic, in other examples, they may be implemented in software and/or firmware. Therefore, as used herein, logic includes hardware, software and/or firmware and may be referred to as code.

In one example, tests of a set of test-repairs are performed and repairs of the set of test-repairs are made based on the tests indicating that the repairs are to be performed. In accordance with one or more aspects, one or more of the repairs to be performed are selected based on priority, such as a predetermined weight, assigned to the test-repairs. In one example, test-repairs having a chosen priority (e.g., highest priority of potential or assigned priorities) are permitted to use the redundant elements in a memory array (or other repairable circuit) prior to other test-repairs. By selectively allowing test-repairs to use redundant elements in memory arrays, memory yield is increased since the testing does not run out of repairs for most integrated circuits.

In one or more aspects, the testing and/or repairing of an integrated circuit is based on one or more criteria, including, but not limited to, prioritization and/or architectural repair limits. This improves the functioning of the integrated circuit by enabling the more significant repairs to be made, improving functionality. For instance, if memory arrays are being repaired, then memory yield is increased, as well as processing that uses memory, since memory failures are repaired. Thus, processing that uses the integrated circuits is improved, including computing devices (e.g., processors, computers, etc.), mobile phones, televisions, automobiles, sensors and/or other electronic devices. Many examples are possible.

In one or more aspects, a method is provided that includes repairing an integrated circuit. The repairing includes selecting a set of test-repairs of a plurality of sets of test-repairs generated to test the integrated circuit. The plurality of sets of test-repairs being assigned one or more priorities based on one or more predefined criteria related to the integrated circuit. The selecting is based on a chosen priority of the one or more priorities, in which the set of test-repairs selected has the chosen priority. One or more tests of the set of test-repairs are executed on the integrated circuit and a number of repairs of the set of test-repairs to be performed on the integrated circuit is determined, based on the executing of the one or more tests of the set of test-repairs. It is evaluated whether the number of repairs to be performed is outside one or more architectural limits assigned to the integrated circuit. Processing to perform selective repairs on the integrated circuit is performed based on the evaluating indicating the number of repairs is outside the one or more architectural limits assigned to the integrated circuit. By repairing the integrated circuit based on priorities, more repairs are performed, increasing the performance of the integrated circuit.

Additionally, or alternatively, in one example, the integrated circuit includes one or more units of circuits, the chosen priority is a highest priority compared to other priorities of the one or more priorities, and the performing processing includes downgrading one unit of circuits of the one or more units of circuits. Based on there being more than the one unit of circuits, one or more repairs are to be applied to at least one other unit of circuits of the one or more units of circuits. The one or more repairs are at least part of the selective repairs. By repairing the integrated circuit based on priorities, more repairs are performed, increasing the performance of the integrated circuit. Further, by performing the highest priority repairs first, the repairs that are most critical to the operation of the integrated circuit are applied first. This allows, for instance, tests that have higher priority to use the redundant elements in a unit of circuits.

Additionally, or alternatively, in one example, the performing processing includes applying at least one repair, but less than all repairs, of the number of repairs to the one unit of circuits. The at least one repair being of the set of test-repairs and part of the selective repairs. By selectively applying repairs, even less than all the repairs, the integrated circuit is still usable, increasing the performance of the integrated circuit, as well as devices that use the integrated circuit.

Additionally, or alternatively, in one example, at least, the selecting, the executing and the evaluating are repeated one or more times for one or more other chosen priorities of the one or more priorities. This allows further selective processing, performing more repairs and increasing the robustness of the integrated circuit.

Additionally, or alternatively, in one example, the one unit of circuits includes a memory array. By repairing the integrated circuit based on priorities, more repairs are performed, increasing performance of the integrated circuit. Further, by performing the highest priority repairs first, the repairs that are most critical to the operation of the integrated circuit are applied first. This allows, for instance, the tests that have the higher priority to use the redundant elements in a unit of circuits, such as a memory array.

Additionally, or alternatively, in one example, the integrated circuit includes a plurality of units of circuits, the chosen priority is a lower priority compared to a highest priority of the one or more priorities, and the performing processing includes bypassing repairs of one unit of circuits of the plurality of units of circuits to repair other units of circuits of the plurality of units of circuits. By bypassing some repairs and allowing other repairs, the repairs that are most important are performed, enabling the best performance and functionality of the integrated circuit.

Additionally, or alternatively, in one example, the number of repairs is applied based on the evaluating indicating that the number of repairs is within the one or more architectural limits assigned to the integrated circuit. Applying the repairs corrects defects in the integrated circuit, improving performance and/or functionality of the integrated circuit.

Additionally, or alternatively, in one example, at least, the selecting, the executing and the evaluating are repeated one or more times for one or more other chosen priorities of the one or more priorities. This allows further selective processing, performing more repairs and increasing the robustness of the integrated circuit. Yield-ability and reliability of the integrated circuit are improved.

Additionally, or alternatively, in one example, the one or more architectural limits include an integrated circuit repair limit assigned to the integrated circuit. The integrated circuit repair limit provides a limit on the number of repairs to be performed on the integrated circuit to ensure the integrity of the integrated circuit.

Additionally, or alternatively, in one example, the integrated circuit includes a plurality of units of circuits, and wherein the one or more architectural limits include one or more repair limits assigned to the unit of circuits. The repair limits assigned to the units of circuits facilitate the testing and repairing of more units of circuits, thus improving the functioning and performance of the integrated circuit.

In accordance with one or more aspects, each of the embodiments is separable and optional from one another. Further, features of an embodiment may be separable and optional from each other. Moreover, embodiments and/or features may be combined with one another.

In one or more aspects, an integrated circuit is provided that includes logic to perform operations including repairing an integrated circuit. The repairing includes selecting a set of test-repairs of a plurality of sets of test-repairs generated to test the integrated circuit. The plurality of sets of test-repairs being assigned one or more priorities based on one or more predefined criteria related to the integrated circuit. The selecting is based on a chosen priority of the one or more priorities, in which the set of test-repairs selected has the chosen priority. One or more tests of the set of test-repairs are executed on the integrated circuit and a number of repairs of the set of test-repairs to be performed on the integrated circuit is determined, based on the executing of the one or more tests of the set of test-repairs. It is evaluated whether the number of repairs to be performed is outside one or more architectural limits assigned to the integrated circuit. Processing to perform selective repairs on the integrated circuit is performed based on the evaluating indicating the number of repairs is outside the one or more architectural limits assigned to the integrated circuit. By repairing the integrated circuit based on priorities, more repairs are performed, increasing the performance of the integrated circuit.

Additionally, or alternatively, in one example, the integrated circuit includes one or more units of circuits, the chosen priority is a highest priority compared to other priorities of the one or more priorities, and the performing processing includes downgrading one unit of circuits of the one or more units of circuits. Based on there being more than the one unit of circuits, one or more repairs are to be applied to at least one other unit of circuits of the one or more units of circuits. The one or more repairs are at least part of the selective repairs. By repairing the integrated circuit based on priorities, more repairs are performed, increasing the performance of the integrated circuit. Further, by performing the highest priority repairs first, the repairs that are most critical to the operation of the integrated circuit are applied first. This allows, for instance, tests that have higher priority to use the redundant elements in a unit of circuits.

Additionally, or alternatively, in one example, the performing processing includes applying at least one repair, but less than all repairs, of the number of repairs to the one unit of circuits. The at least one repair being of the set of test-repairs and part of the selective repairs. By selectively applying repairs, even less than all the repairs, the integrated circuit is still usable, increasing the performance of the integrated circuit, as well as devices that use the integrated circuit.

Additionally, or alternatively, in one example, the integrated circuit includes a plurality of units of circuits, the chosen priority is a lower priority compared to a highest priority of the one or more priorities, and the performing processing includes bypassing repairs of one unit of circuits of the plurality of units of circuits to repair other units of circuits of the plurality of units of circuits. By bypassing some repairs and allowing other repairs, the repairs that are most important are performed, enabling the best performance and functionality of the integrated circuit.

Additionally, or alternatively, in one example, the operations further include applying the number of repairs based on the evaluating indicating that the number of repairs is within the one or more architectural limits assigned to the integrated circuit. Applying the repairs corrects defects in the integrated circuit, improving the performance and/or functionality of the integrated circuit.

In accordance with one or more aspects, each of the embodiments is separable and optional from one another. Further, features of an embodiment may be separable and optional from each other. Moreover, embodiments and/or features may be combined with one another.

In one or more aspects, a computer program product is provided that includes a set of one or more computer-readable storage media, and program instructions, collectively stored in the set of one or more computer-readable storage media, for causing at least one computing device of a computing environment to perform computer operations. The computer operations include repairing an integrated circuit. The repairing includes selecting a set of test-repairs of a plurality of sets of test-repairs generated to test the integrated circuit. The plurality of sets of test-repairs being assigned one or more priorities based on one or more predefined criteria related to the integrated circuit. The selecting is based on a chosen priority of the one or more priorities, in which the set of test-repairs selected has the chosen priority. One or more tests of the set of test-repairs are executed on the integrated circuit and a number of repairs of the set of test-repairs to be performed on the integrated circuit is determined, based on the executing of the one or more tests of the set of test-repairs. It is evaluated whether the number of repairs to be performed is outside one or more architectural limits assigned to the integrated circuit. Processing to perform selective repairs on the integrated circuit is performed based on the evaluating indicating the number of repairs is outside the one or more architectural limits assigned to the integrated circuit. By repairing the integrated circuit based on priorities, more repairs are performed, increasing the performance of the integrated circuit.

Additionally, or alternatively, in one example, the integrated circuit includes one or more units of circuits, the chosen priority is a highest priority compared to other priorities of the one or more priorities, and the performing processing includes downgrading one unit of circuits of the one or more units of circuits. Based on there being more than the one unit of circuits, one or more repairs are to be applied to at least one other unit of circuits of the one or more units of circuits. The one or more repairs are at least part of the selective repairs. By repairing the integrated circuit based on priorities, more repairs are performed, increasing the performance of the integrated circuit. Further, by performing the highest priority repairs first, the repairs that are most critical to the operation of the integrated circuit are applied first. This allows, for instance, tests that have higher priority to use the redundant elements in a unit of circuits.

Additionally, or alternatively, in one example, the performing processing includes applying at least one repair, but less than all repairs, of the number of repairs to the one unit of circuits. The at least one repair being of the set of test-repairs and part of the selective repairs. By selectively applying repairs, even less than all the repairs, the integrated circuit is still usable, increasing the performance of the integrated circuit, as well as devices that use the integrated circuit.

Additionally, or alternatively, in one example, the integrated circuit includes a plurality of units of circuits, the chosen priority is a lower priority compared to a highest priority of the one or more priorities, and the performing processing includes bypassing repairs of one unit of circuits of the plurality of units of circuits to repair other units of circuits of the plurality of units of circuits. By bypassing some repairs and allowing other repairs, the repairs that are most important are performed, enabling the best performance and functionality of the integrated circuit.

Additionally, or alternatively, in one example, the operations further include applying the number of repairs based on the evaluating indicating that the number of repairs is within the one or more architectural limits assigned to the integrated circuit. Applying the repairs corrects defects in the integrated circuit, improving the performance and/or functionality of the integrated circuit.

In accordance with one or more aspects, each of the embodiments is separable and optional from one another. Further, features of an embodiment may be separable and optional from each other. Moreover, embodiments and/or features may be combined with one another.

In one or more aspects, a computer system is provided that includes a set of computing devices of a computing environment, a set of one or more computer-readable storage media and program instructions, collectively stored in the set of one or more computer-readable storage media, for causing at least one computing device of the set of computing devices to perform computer operations. The computer operations include repairing an integrated circuit. The repairing includes selecting a set of test-repairs of a plurality of sets of test-repairs generated to test the integrated circuit. The plurality of sets of test-repairs being assigned one or more priorities based on one or more predefined criteria related to the integrated circuit. The selecting is based on a chosen priority of the one or more priorities, in which the set of test-repairs selected has the chosen priority. One or more tests of the set of test-repairs are executed on the integrated circuit and a number of repairs of the set of test-repairs to be performed on the integrated circuit is determined, based on the executing of the one or more tests of the set of test-repairs. It is evaluated whether the number of repairs to be performed is outside one or more architectural limits assigned to the integrated circuit. Processing to perform selective repairs on the integrated circuit is performed based on the evaluating indicating the number of repairs is outside the one or more architectural limits assigned to the integrated circuit. By repairing the integrated circuit based on priorities, more repairs are performed, increasing the performance of the integrated circuit.

Additionally, or alternatively, in one example, the integrated circuit includes one or more units of circuits, the chosen priority is a highest priority compared to other priorities of the one or more priorities, and the performing processing includes downgrading one unit of circuits of the one or more units of circuits. Based on there being more than the one unit of circuits, one or more repairs are to be applied to at least one other unit of circuits of the one or more units of circuits. The one or more repairs being at least part of the selective repairs. By repairing the integrated circuit based on priorities, more repairs are performed, increasing the performance of the integrated circuit. Further, by performing the highest priority repairs first, the repairs that are most critical to the operation of the integrated circuit are applied first. This allows, for instance, tests that have higher priority to use the redundant elements in a unit of circuits.

Additionally, or alternatively, in one example, the integrated circuit includes a plurality of units of circuits, the chosen priority is a lower priority compared to a highest priority of the one or more priorities, and the performing processing includes bypassing repairs of one unit of circuits of the plurality of units of circuits to repair other units of circuits of the plurality of units of circuits. By bypassing some repairs and allowing other repairs, the repairs that are most important are performed, enabling the best performance and functionality of the integrated circuit.

In accordance with one or more aspects, each of the embodiments is separable and optional from one another. Further, features of an embodiment may be separable and optional from each other. Moreover, embodiments and/or features may be combined with one another.

In one or more aspects, a method is provided that includes repairing an integrated circuit. The integrated circuit is assigned an integrated circuit repair limit and includes a plurality of memory arrays. The plurality of memory arrays is assigned one or more array repair limits. The repairing includes selecting a set of test-repairs of a plurality of sets of test-repairs generated to test the integrated circuit. The plurality of sets of test-repairs is assigned one or more priorities based on one or more predefined criteria related to the integrated circuit. The selecting is based on a chosen priority of the one or more priorities, in which the set of test-repairs selected has the chosen priority. One or more tests of the set of test-repairs are executed on a memory array of the plurality of memory arrays of the integrated circuit. A number of repairs of the set of test-repairs to be performed on the memory array based on the executing of the one or more tests of the set of test-repairs is determined. It is evaluated whether the number of repairs to be performed is outside an array repair limit assigned to the memory array. It is evaluated whether the number of repairs to be performed is outside the integrated circuit repair limit assigned to the integrated circuit. Based on the number of repairs to be performed being outside the array repair limit and the integrated circuit repair limit, it is determined whether the memory array is to be downgraded to a lower priority level compared to the priority level at which it was tested. The memory array is downgraded to the lower priority level to continue repairing one or more other memory arrays of the plurality of memory arrays, based on the determining indicating that the memory array is to be downgraded, in which the integrated circuit is still usable subsequent to the downgrading. Downgrading a memory array of the integrated circuit based on the evaluating indicating the number of repairs is outside the array repair limit and the integrated circuit repair limit enables the integrated circuit to still be usable, increasing the performance and/or functionality of the devices using the integrated circuit. By repairing the integrated circuit based on priorities, more repairs are performed, increasing the performance of the integrated circuit.

Additionally, or alternatively, in one example, the integrated circuit is rejected based on the determining indicating that the memory array is not to be downgraded. This improves processing within a device using the integrated circuit by ensuring that an integrated circuit needing a critical repair is not used.

In accordance with one or more aspects, each of the embodiments is separable and optional from one another. Further, features of an embodiment may be separable and optional from each other. Moreover, embodiments and/or features may be combined with one another.

In one or more aspects, a method is provided that includes repairing an integrated circuit. The integrated circuit includes one or more units of circuits. The repairing includes selecting a set of test-repairs of a plurality of sets of test-repairs generated to test the integrated circuit. The plurality of sets of test-repairs being assigned one or more priorities based on one or more predefined criteria related to the integrated circuit. The selecting is based on a chosen priority of the one or more priorities, in which the set of test-repairs selected has the chosen priority. One or more tests of the set of test-repairs are executed on the integrated circuit and a number of repairs of the set of test-repairs to be performed on the integrated circuit is determined, based on the executing of the one or more tests of the set of test-repairs. It is evaluated whether the number of repairs to be performed is outside one or more architectural limits assigned to the integrated circuit. Processing to perform selective repairs on the integrated circuit is performed based on the evaluating indicating the number of repairs is outside the one or more architectural limits assigned to the integrated circuit. Based on the chosen priority being a highest priority compared to other priorities of the one or more priorities, the performing processing includes downgrading one unit of circuits of the one or more units of circuits. Based on there being more than the one unit of circuits, one or more repairs are to be applied to at least one other unit of circuits of the one or more units of circuits. The one or more repairs are at least part of the selective repairs. Based on the chosen priority being a lower priority compared to a highest priority of the one or more priorities, the performing processing includes bypassing repairs of one unit of circuits of the plurality of units of circuits to repair other units of circuits of the plurality of units of circuits. By bypassing some repairs and allowing other repairs, the repairs that are most important are performed, enabling the best performance and functionality of the integrated circuit. By repairing the integrated circuit based on priorities, more repairs are performed, increasing the performance of the integrated circuit. Further, by performing the highest priority repairs first, the repairs that are most critical to the operation of the integrated circuit are applied first. This allows, for instance, tests that have higher priority to use the redundant elements in a unit of circuits.

In accordance with one or more aspects, each of the embodiments is separable and optional from one another. Further, features of an embodiment may be separable and optional from each other. Moreover, embodiments and/or features may be combined with one another.

In one or more aspects, a method is provided that includes repairing an integrated circuit that includes a plurality of units of circuits. The repairing includes selecting a set of test-repairs of a plurality of sets of test-repairs generated to test the integrated circuit. The plurality of sets of test-repairs being assigned one or more priorities based on one or more predefined criteria related to the integrated circuit. The selecting is based on a chosen priority of the one or more priorities, in which the set of test-repairs selected has the chosen priority. One or more tests of the set of test-repairs are executed on the integrated circuit and a number of repairs of the set of test-repairs to be performed on the integrated circuit is determined based on the executing of the one or more tests of the set of test-repairs. It is evaluated whether the number of repairs to be performed is outside one or more architectural limits assigned to the integrated circuit, in which the one or more architectural limits include an integrated circuit repair limit assigned to the integrated circuit and one or more repair limits assigned to the plurality of units of circuits. Processing to perform selective repairs on the integrated circuit is performed based on the evaluating indicating the number of repairs is outside the one or more architectural limits assigned to the integrated circuit. By repairing the integrated circuit based on priorities, more repairs are performed, increasing the performance of the integrated circuit. The integrated circuit repair limit provides a limit on the number of repairs to be performed on the integrated circuit to ensure the integrity of the integrated circuit, and the repair limits assigned to the units of circuits facilitate the testing and repairing of more units of circuits, thus improving the functioning and performance of the integrated circuit.

In accordance with one or more aspects, each of the embodiments is separable and optional from one another. Further, features of an embodiment may be separable and optional from each other. Moreover, embodiments and/or features may be combined with one another.

Methods, integrated circuits, computer systems and computer program products relating to one or more aspects are described and claimed herein. Each of the embodiments of the method may be embodiments of each integrated circuit, each computer system and/or each computer program product and vice-versa. Further, each of the embodiments is separable and optional from one another. Moreover, embodiments may be combined with one another. Further, features of an embodiment may be separable and optional from each other. Moreover, each of the embodiments and/or features of the methods may be combinable with aspects and/or embodiments of each integrated circuit, computer system and/or computer program product, and vice-versa. Many examples are possible.

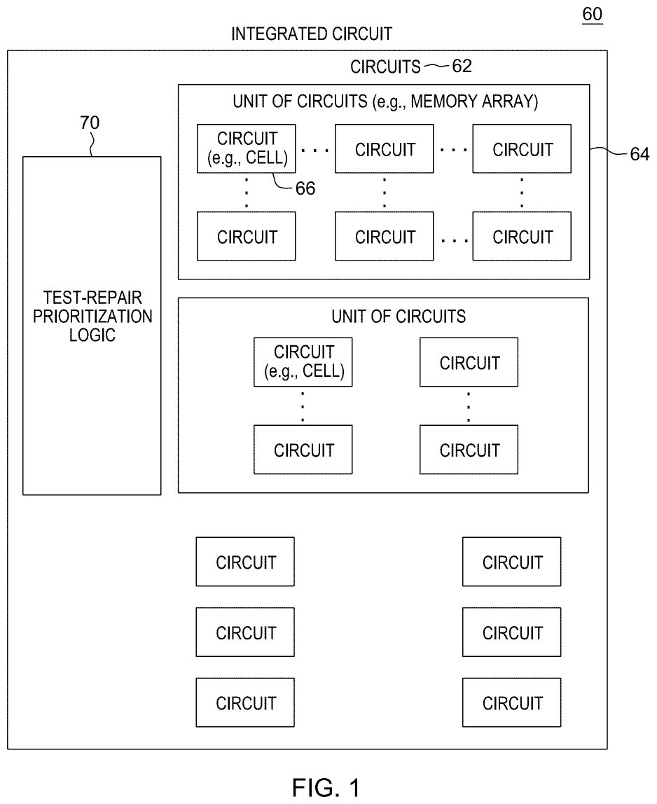

One or more aspects of the present disclosure are incorporated in, performed and/or used by an integrated circuit. For example, in one or more aspects, a capability is provided to selectively perform testing and/or repairing of an integrated circuit. Integrated circuits are used in electronic devices, including, but not limited to, computing devices (e.g., processors, computers, etc.), mobile phones, televisions, automobiles, sensors, other electronic devices, etc. As depicted in FIG. 1, an integrated circuit 60 includes a plurality of circuits 62 (e.g., electronic circuits). The circuits consist of, for instance, electronic components, such as transistors, resistors and/or capacitors, as well as their interconnections. The components are etched in, e.g., a semiconductor material, such as silicon. The number of circuits in an integrated circuit can vary, and the depiction of circuits in FIG. 1 is not necessarily indicative of the number of circuits in an integrated circuit. An integrated circuit can have more (e.g., even many more) or fewer circuits than shown. Many examples are possible.

In one example, circuits 62 may include one or more units of circuits 64, and each unit of circuits includes one or more circuits 66. In one example, a unit of circuits performs a particular function, such as memory. In such an example, the unit of circuits is referred to as a memory array, and circuits of the memory array are referred to as cells (e.g., memory cells). Other examples are possible, however, including other functions.

In one example, integrated circuit 60 includes logic, such as test-repair prioritization logic 70, to perform selective testing and/or repairing of the integrated circuit based on, e.g., prioritization and/or architectural limits. The testing and/or repairing of the integrated circuit includes testing and/or repairing individual circuits and/or units of circuits. As an example, test-repair prioritization logic 70 is a built-in self-test embedded in the integrated circuit (e.g., integrated circuit 60). In another example, the logic is coupled but external to the integrated circuit. Other examples are possible. As one example, test-repair prioritization logic 70 is hardware. In other examples, test-repair prioritization logic may be hardware, software and/or firmware, and in embodiments, is referred to as code.

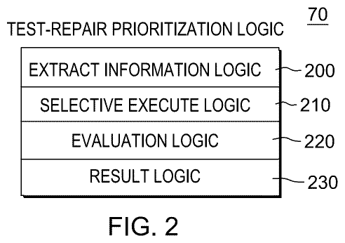

In one example, referring to FIG. 2, test-repair prioritization logic (e.g., test-repair prioritization logic 70) includes various logic to be used to perform selective testing and/or repairing of integrated circuits. As examples, the selective testing and/or repairing is based on priorities assigned to sets of test-repairs used to test and/or repair one or more of the circuits and/or units of circuits, and/or based on architectural limits, as described herein.

In one example, test-repair prioritization logic 70 includes, for instance, extract information logic 200 to be used to extract information related to selective testing and repairing of a given integrated circuit (information includes, e.g., one or more of: priorities, architectural limits, test-repairs to be performed or indication or location of the same, indication of integrated circuit to be tested/repaired, etc.); selective execute logic 210 to be used to selectively execute one or more tests and/or repair operations; evaluation logic 220 to be used to evaluate whether further testing and/or repairs are to be performed; and result logic 230 to be used to provide a result of the selective testing/repairing. Additional, less and/or other test-repair prioritization logic may be used to implement selective testing and/or repairing of an integrated circuit, in which the selectivity employs priorities and/or architectural limits. Other variations are possible. Although various test-repair prioritization logic is described, test-repair prioritization logic 70 may include additional, less and/or different logic. Particular subsets of test-repair prioritization logic may include additional logic, less logic, and/or different logic. Further, additional, less and/or other logic may be used for selective testing and/or repairing and/or to perform related tasks. Many variations are possible.

In one example, the test-repair prioritization logic (e.g., test-repair prioritization logic 70) is used, in accordance with one or more aspects of the present disclosure, to selectively perform tests and/or repairs on an integrated circuit, in which the selection is based on, for instance, prioritization of sets of test-repairs and/or architectural limits assigned to the integrated circuit. In one example, a plurality of units of circuits of an integrated circuit is being tested and/or repaired. In this example, the units of circuits are memory arrays; however, other repairable circuits may benefit from and/or use one or more aspects of the present disclosure. In this particular example, each memory array has a redundancy limitation of, e.g., 1 repair allowed by design. This repair limit (e.g., array (or other unit of circuits) repair limit) is referred to herein as an architectural limit, which is changeable. Another architectural limit is an integrated circuit repair limit of N, in which the processor is limited to perform N repairs. Again, this architectural limit is changeable. Additional, fewer and/or other architectural limits are possible. Further, each architectural limit may have different values than those described herein. Many examples are possible.

In one or more aspects, some repairs are considered more important than others for a variety of reasons, including, but not limited to, customer performance (e.g., performance of the device in which the integrated circuit is included). Thus, in accordance with one or more aspects, the more important repairs are prioritized over others. Further, one or more repairs may be considered critical or must fix in that if they cannot be performed, then the integrated circuit is to be rejected, while other tests/repairs are considered not critical (e.g., optional or fix if possible), and thus, the integrated circuit still may be used even if those repairs are not performed.

As an example, the priority of tests/repairs is indicated by weights assigned to the tests/repairs. Although weights are used in one example, other mechanisms may be used to assign priority. In one example, priorities 1 through n are provided, in which priority 1 is considered the highest priority compared to the other potential or assigned priorities (e.g., 2 through n). Many other examples exist, including, but not limited to, a reversal of the priorities, in which priority 1 is considered the lowest priority compared to the other potential or assigned priorities (e.g., 2 through n). Other examples are possible.

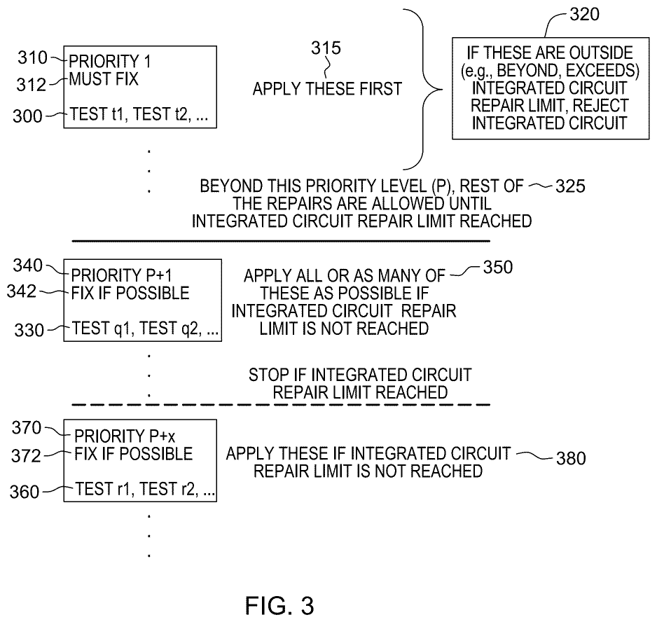

One example of using prioritization and at least one architectural limit to selectively perform tests/repairs is described with reference to FIG. 3. In this example, an integrated circuit repair limit is employed. However, in other examples, the integrated circuit repair limit, an array (or other unit of circuits) repair limit and/or other limits may be used.

In one example, a set of tests/repairs (e.g., Test t1, Test t2, . . . 300) is considered a high priority 310 (e.g., priority (P) 1) and critical (must fix 312) to use the integrated circuit. Thus, the repairs of this set of tests-repairs are applied first 315, meaning prior to repairs of other sets of tests-repairs that have a lower priority. If these repairs are outside (e.g., beyond, exceeds) the integrated circuit repair limit, then in one example, the integrated circuit is rejected 320, since the repairs are considered a must fix for the integrated circuit to be used.

If other repairs exist beyond the high priority level (e.g., priority 1), the remaining repairs at the lower levels are allowed (e.g., made, performed, executed, applied, etc.) until the integrated circuit repair limit is reached 325. For example, for a next level of priority 340 (e.g., priority P+1), repairs of another set of tests-repairs (e.g., Test q1, Test q2, . . . 330) are to be applied, if possible 342 (e.g., fix if possible). That is, all or as many of the repairs in this other set of test-repairs, as possible, are applied, assuming the integrated circuit repair limit is not reached 350.

Thereafter, in one example, repairs of at least one other set of test-repairs (e.g., Test r1, Test r2, . . . 360) that are at one or more lower priorities 370 (e.g., priority P+x) are applied, if possible 372 (e.g., fix if possible). That is, these repairs are applied if the integrated circuit repair limit is not reached 380. Other examples are possible.

In one example, a decision of whether to perform a repair is based on whether a high-end of a limit has been reached (e.g., equal or exceeded); however, in other examples, the decision can be based on other predefined relationships with the limit, such as a low-end of the limit. Various examples exist. Thus, the term outside a limit is used herein to include various predefined relationships with the limit. In one example, a repair is not performed in the examples herein if the repair is outside (e.g., exceeds, is beyond, etc.) one or more architectural limits. In another example, a repair is not performed in the examples herein if the repair is outside (e.g., below, etc.) one or more architectural limits. Other examples are possible.

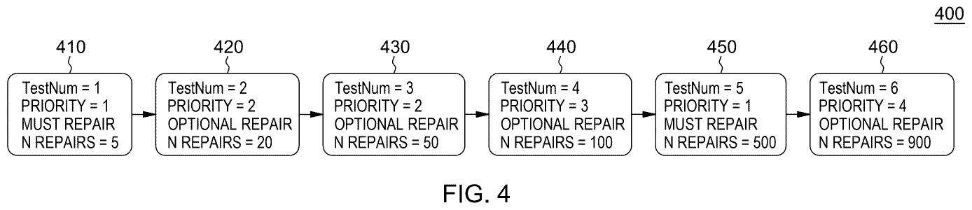

Further details of one embodiment of using priorities and one or more architectural limits are described with reference to FIG. 4. In this example 400, sets of test-repairs are being performed on memory arrays of an integrated circuit. Each set of test-repairs (e.g., TestNum) has a priority associated therewith from a highest priority, e.g., 1 to a lowest priority, e.g., 4. It is assumed that there is an integrated circuit repair limit of 1000 repairs and that no array repair limit is exceeded (e.g., outside the array repair limit) for those memory arrays in which test-repairs with the highest available priority (e.g., Priority=1) are to be applied. Based on these assumptions, the results for this example include:

For TestNum=1 (410): All repairs (e.g., 5) are performed (e.g., applied), as they are priority 1 (must repair) and do not violate any architectural limits (e.g., array repair limit and integrated circuit repair limit). If they did violate any architectural limits, such as array redundancy limitations (i.e., array repair limits) and/or integrated circuit repair limits, the integrated circuit is rejected.

For TestNum=2 (420): All repairs (e.g., 20) are performed and do not violate any architectural limits (e.g., array repair limit and integrated circuit repair limit). If any repair did violate an architectural limit (e.g., any array redundancy limitations (array repair limits) or an integrated circuit repair limit), the problematic repair is not performed, since it has a priority of 2, which is an optional repair (fix if possible), in this example. The integrated circuit is still shippable.

For TestNum=3 (430): All repairs (e.g., 50) are performed and do not violate any architectural limits (e.g., array repair limit and integrated circuit repair limit). If any repair did violate an architectural limit (e.g., any array redundancy limitations (array repair limits) or an integrated circuit repair limit), the problematic repair is not performed, since it has a priority of 2, which is an optional repair (fix if possible), in this example. The integrated circuit is still shippable.

For TestNum=4 (440): All repairs (e.g., 100) are performed and do not violate any architectural limits (e.g., array repair limit and integrated circuit repair limit). If any repair did violate an architectural limit (e.g., any array redundancy limitations (array repair limits) or an integrated circuit repair limit), the problematic repair is not performed, since it has a priority of 3, which is an optional repair (fix if possible), in this example. The integrated circuit is still shippable.

For TestNum=5 (450): All repairs (e.g., 500) are performed (e.g., applied), as they are priority 1 (must repair) and do not violate any architectural limits (e.g., array repair limit and integrated circuit repair limit). If they did violate any architectural limits, such as array redundancy limitations (i.e., array repair limits) and/or integrated circuit repair limits, the integrated circuit is rejected.

For TestNum=6 (460): Only 325 of the 900 repairs from TestNum 6 are performed, due to the integrated circuit repair limit (e.g., N=1000 has been reached). The remaining 575 repairs are rejected, as they are deemed the lowest priority (e.g., priority 4, in this example, and thus, optional (fix if possible)) for the customer. The integrated circuit is still shippable.

The tests themselves of the sets of test-repairs (e.g., TestNum) could be performed out of order, but the priority of the repairs is still applied. For instance, although TestNum 5 is running after TestNums 2, 3, 4, since its priority is 1, TestNums 1, 5 repairs are applied first. Then, TestNums 2, 3 are examined to see if these will fit within, e.g., the integrated circuit level repair limit followed by TestNum 4. In some cases, TestNum 5 repairs could replace TestNums 2, 3, or 4 repairs since TestNum 5 repairs are deemed higher priority. Other examples are possible.

This approach allows the repair of all critical defects, as well as most marginal defects, while still maintaining manufacturability from a yield perspective. Other examples are possible.

In one or more examples, the priorities used for the repairs are based on one or more predefined criteria related to the integrated circuit. One predefined criterion is test priority, in which priorities assigned to the sets of test-repairs are based on the tests and/or repairs themselves. For instance, the tests and/or repairs of a set of test-repairs may be considered a higher priority than other tests and/or repairs of other sets of test-repairs based on one or more considerations (e.g., importance of the repair to the functioning of the circuit, security, performance, etc.). Other considerations are possible.

In other examples, the predefined criteria may include application priority, chiplet priority, recoverability priority, and/or other priority criteria. Further details relating to one or more of these priorities are described below.

For application priority, the memory arrays (or other units of circuits) considered most critical (based on one or more considerations) are prioritized over memory arrays (or other units of circuits) considered less critical. For example, an L1 cache of a hierarchical cache may receive a higher priority of repairs over a branch prediction array, since branch prediction errors are well-tolerated compared to cache misses. Thus, in this example, a set of test-repairs may be developed for a particular type of memory array (or other unit of circuits) and that set of test-repairs is assigned a higher priority (e.g., priority 1). In another example, the memory arrays (or other units of circuits) are assigned priorities and repairs are performed on the memory arrays (or other units of circuits) based on the priorities. Other examples are possible.

For chiplet priority, a chiplet (e.g., a small integrated circuit that is part of an integrated circuit) may be downgraded (e.g., unenabled, assigned a lower chiplet priority, etc.) if, for instance, critical repairs do not fit within, e.g., the integrated circuit repair limit. If a chiplet in an integrated circuit can be downgraded when a failure is encountered in that chiplet, then the memory arrays (or other units of circuits) in these types of chiplets are assigned a lower priority of repair when, e.g., the integrated circuit repair limit is reached. As an example, the sets of test-repairs to be used to test and/or repair these chiplets are assigned (or reassigned) a lower priority to indicate that the repairs are not considered critical (instead, optional or fix if possible). If the integrated circuit repair limit is reached, this chiplet may be downgraded, making more repairs available for the critical chiplets. This way, more repairs may be routed to the critical chiplets in an integrated circuit and still yield a usable, but downgraded, integrated circuit. In one example, if the integrated circuit repair limit is reached, non-redundant chiplets are prioritized over redundant chiplets. Other examples are possible.

For recoverability priority, repairs for memory arrays (or other units of circuits) are prioritized based on the recoverability of the array failures. Some arrays (e.g., on a chiplet) are recoverable easily. For example, an application that is parity protected is able to tolerate a failure versus an application that does not have any recovery or error protection and correction features. Thus, in this example, a set of test-repairs may be developed for a particular type of memory array (or other unit of circuits) and that set of test-repairs is assigned a higher priority (e.g., priority 1). In another example, the memory arrays (or other units of circuits) are assigned priorities and repairs are performed on the memory arrays (or other units of circuits) based on the priorities. Other examples are possible.

In one or more examples, one or more priority criteria may be combined to determine a priority to be assigned to a set of test-repairs. For example, multiple tests are assigned different priority levels by virtue of importance of, e.g., test, criticality of array (or other unit of circuits), criticality of integrated circuit level application, criticality of chiplet, recoverability of chiplet/application or a combination of one or more of above. Other examples and/or considerations are possible.

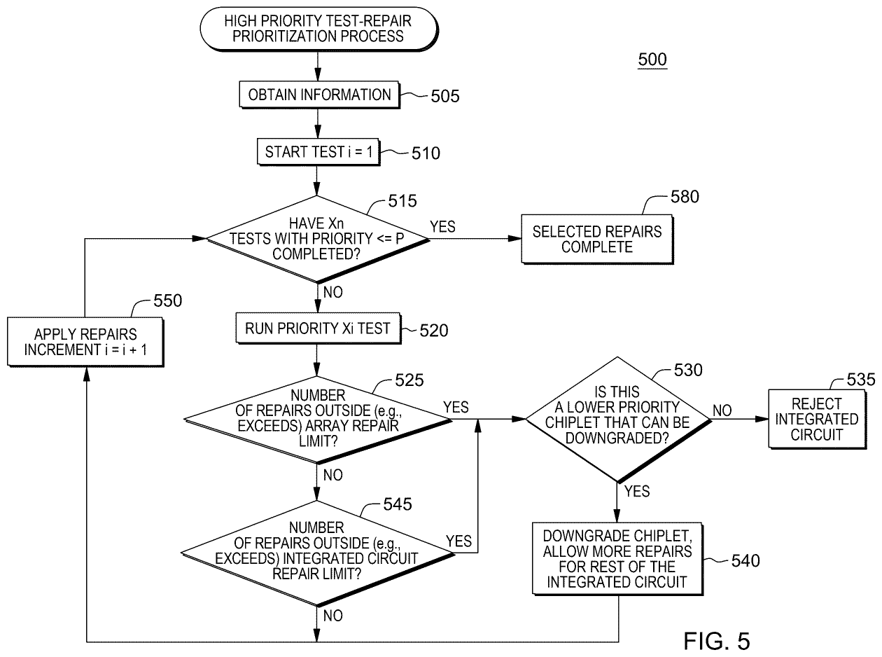

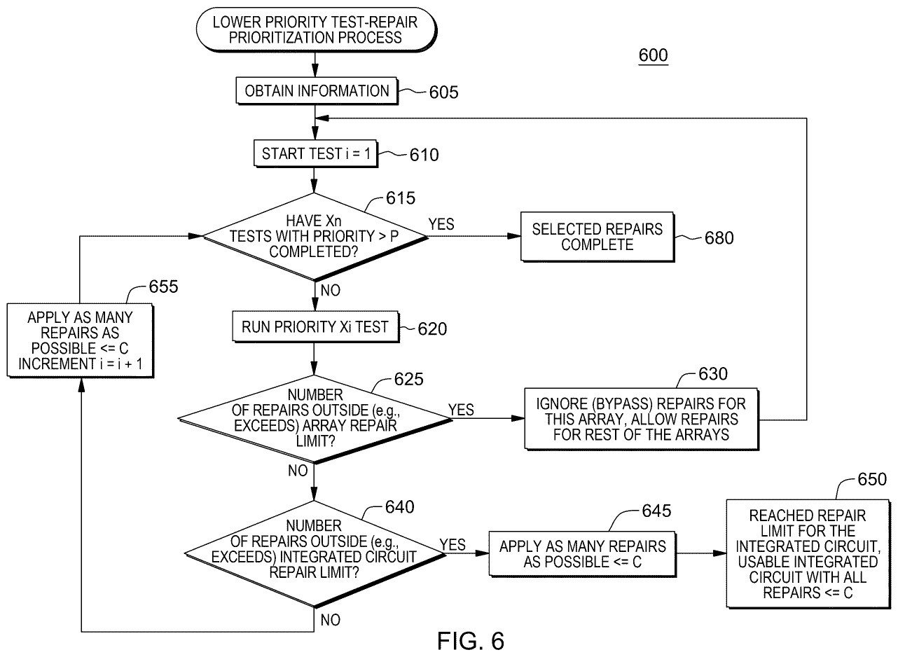

Further details regarding selectively executing tests/repairs based on prioritization and/or architectural limits are described with reference to FIGS. 5-6. FIG. 5 depicts one example of a process relating to high priority (e.g., critical or must fix) tests/repairs; and FIG. 6 depicts one example of a process relating to lower priority (e.g., optional or fix if possible) tests/repairs. In one or more examples, each process is implemented using test-repair prioritization logic (e.g., test-repair prioritization logic 70) and/or other logic embedded and executed by the integrated circuit.

Referring to FIG. 5, in one example, a high priority test-repair prioritization process 500 (also referred to as process 500) obtains 505 (e.g., extracts, pulls, receives, is provided, etc.) certain information (e.g., using extract information logic 200) regarding an integrated circuit and/or test-repairs to be performed for the integrated circuit. For instance, the information obtained includes: repairs (e.g., all repairs) at a selected priority (e.g., less than or equal to P (<=P), where, e.g., P=1) are to be applied; as many repairs as possible for tests with one or more other selected priorities (e.g., greater than P (>P), where, e.g., P=1) are to be applied; an integrated circuit repair limit is equal to C; an array repair limit is equal to R; and tests X1 . . . Xn are to be run. Additional, less and/or other information may be obtained.

In one example, process 500 commences 510 the testing for a memory array (also referred to as array) or other unit of circuits by initiating a variable (e.g., i) to an initial value (e.g., 1) and starting test X1 of a set of Xn test-repairs. Process 500 determines 515 whether a number (e.g., Xn) of tests with a chosen priority (e.g., priority<=P; e.g., P=1) have completed for the memory array. Based on the maximum number of tests (e.g., Xn) for the memory array not being completed, process 500 executes 520 (e.g., runs, processes, performs, etc.) Xi test (e.g., using selective execute logic 210).

Process 500 determines 525 (e.g., using evaluation logic 220) whether the number of repairs indicated from the testing is outside (e.g., exceeds) an array repair limit (R). Should the number of repairs to be applied be outside (e.g., exceeds) the array repair limit, in one example, process 500 evaluates 530 (e.g., using evaluation logic 220) whether the testing is for a lower priority chiplet that can be downgraded. Based on the chiplet not being able to be downgraded, process 500 rejects 535 (e.g., using result logic 230) the integrated circuit (i.e., chip) and the integrated circuit is not used.

However, if process 500 determines 530 that the testing is for a lower priority chiplet that can be downgraded, process 500 downgrades 540 the chiplet to allow more repairs for the rest of the integrated circuit. For instance, the chiplet is downgraded by reassigning the set of test-repairs used to test and/or repair the chiplet to a lower priority (e.g., >P). Processing continues to block 550, in which, as examples, depending on design, process 500 applies no repairs for this chiplet and reevaluates the chiplet as a lower priority (e.g., FIG. 6) or applies repairs up to the array repair limit and/or reevaluates the chiplet as a lower priority (e.g., FIG. 6). Other examples are possible. Further process 500 increments i (e.g., by 1).

Returning to inquiry 525, if the number of repairs indicated from the testing is not outside (e.g., does not exceed) the array repair limit, process 500 determines 545 whether the number of repairs is outside (e.g., exceeds) the integrated circuit repair limit for the memory array being tested. Should the number of repairs to be applied be outside (e.g., exceeds) the integrated circuit repair limit, process 500 continues with determining 530 whether the testing is of a lower priority chiplet that can be downgraded. However, if the number of repairs to be applied is not outside (e.g., does not exceed) the integrated circuit repair limit (545), process 500 executes 550 (e.g., applies) the repairs and increments (e.g., by 1) the variable (e.g., i). Process 500 continues with determining 515 whether the requested tests/repairs have completed.

Based on the requested tests-repairs (e.g., set of Xn tests-repairs) being completed (515), process 500 obtains 580 (e.g., is provided an indication, signaled, determines from count of i etc., e.g., using result logic 230) that the selected repairs (e.g., set of Xn test-repairs) have completed. In one example, the high priority test-repair prioritization process 500 may be repeated for other memory arrays (or other units of circuits) of the integrated circuit that are to be tested at the same chosen priority. Other examples are possible.

Referring to FIG. 6, in one example, a lower priority test-repair prioritization process 600 (also referred to as process 600) obtains 605 (e.g., extracts, pulls, receives, is provided, etc.) certain information (e.g., using extract information logic 200) regarding an integrated circuit and/or test/repairs to be performed for the integrated circuit. For instance, the information includes: repairs (e.g., all repairs) at a chosen priority (e.g., less than or equal to P (<=P, where, e.g., P=1)) are to be applied; as many repairs as possible for tests with one or more other chosen priorities (e.g., greater than P (>P, where, e.g., P=1)) are to be applied; an integrated circuit repair limit is equal to C; an array repair limit is equal to R; and tests X1 . . . Xn are to be run. Additional, less and/or other information may be obtained.

In one example, process 600 commences 610 the testing for a memory array (also referred to as array) or other unit of circuits by initiating a variable (e.g., i) to an initial value (e.g., 1) and starting test X1 of a set of Xn test-repairs. Process 600 determines 615 whether a number (e.g., Xn) of tests with a chosen priority (e.g., priority>P, where, e.g., P=1) have completed for the memory array. Based on the maximum number of tests (e.g., Xn) for the memory array at the chosen priority not being completed, process 600 executes 620 (e.g., runs, processes, performs, etc.) Xi test (e.g., using selective execute logic 210).

Process 600 determines 625 (e.g., using evaluation logic 220) whether the number of repairs indicated from the testing is outside (e.g., exceeds) an array repair limit (R) for the memory array being tested. Should the number of repairs to be applied be outside (e.g., exceeds) the array repair limit, in one example, process 600 ignores 630 (e.g., bypasses) the repairs for this array, and allows repairs for the rest of the arrays (or other unit of circuits), assuming such arrays. Thus, the processing is repeated (e.g., go to 610) for a next array (or other unit of circuit).

However, if the number of repairs to be applied is not outside (e.g., has not exceeded) the array repair limit, process 600 determines 640 whether the number of repairs is outside (e.g., exceeds) the integrated circuit repair limit. Should the number of repairs to be applied be outside (e.g., exceeds) the integrated circuit repair limit, process 600 continues with applying 645 (e.g., using selective execute logic 210) as many repairs as possible less than or equal to the integrated circuit repair limit (C) and based on reaching the integrated circuit repair limit, the integrated circuit is usable 650 with the repairs (e.g., as indicated using result logic 230). However, if the number of repairs to be applied is not outside (e.g., does not exceed) the integrated circuit repair limit (640), process 600 executes 655 (e.g., applies; e.g., using selective execute logic 210) as many repairs as possible less than or equal to the integrated circuit repair limit and increments (e.g., by 1) the variable (e.g., i). Process 600 continues with determining 615 whether the requested tests/repairs have completed.

Based on the requested tests-repairs (e.g., set of Xn tests-repairs) being completed (615), process 600 obtains 680 (e.g., is provided an indication, signaled, determines from count of i, etc.; e.g., using result logic 230) that the selected repairs (e.g., set of Xn test-repairs) have completed. In one example, the lower priority test-repair prioritization process 600 may be repeated for other memory arrays (or other units of circuits) of the integrated circuit; and/or process 600 may be repeated for other priorities. Other examples are possible.

In one or more aspects, the logic of FIGS. 5-6 may be combined such that, for instance, the logic of FIG. 5 is used initially to apply the repairs with the highest priority and then, the logic of FIG. 6 is used to apply the repairs with other than the highest priority. Other examples are possible. In both FIGS. 5 and 6, based on the number of repairs being outside one or more architectural limits assigned to the integrated circuit, processing is performed to perform selective repairs on the integrated circuit. For example, in FIG. 5, the chiplet is downgraded, in one or more instances, enabling selective repairs (e.g., selected repairs of the current set of test-repairs and/or selected repairs of other sets of test-repairs for other memory arrays) to be applied. In another example, in FIG. 6, the processing includes bypassing repairs for the currently tested memory array to enable repairs for other memory arrays. Other examples are possible.

In one or more examples, the integrated circuit repair limit is an architectural limit, which may or may not be a physical limit. It may be an artificial limit that may be used for saving repairs for a later test operation. Other examples are possible.

Although various embodiments are described herein, other embodiments may utilize repair prioritization for yield-ability and reliability of integrated circuits. In one or more embodiments, various criteria may be used to define priorities. In one or more embodiments, although memory arrays (also referred to as memory blocks or arrays) are used in the examples, one or more aspects may be applied to any repairable circuit, including but not limited to, input/output circuits, logic circuits and/or dynamic random access memory. Other examples are also possible.

One or more aspects are applicable to on-chip repair or off-chip repair, as well as volatile storage and then written to an on-chip fuse block. Other examples are possible.

The term repair is used interchangeably herein, when appropriate from the context, with a fail or failure, since a fail or failure drives a repair.

One or more aspects selectively apply repairs based on one or more criteria, such as priority and/or architectural limits (and/or other criteria). One or more aspects take into consideration an integrated circuit repair limit.

One or more aspects include: at an integrated circuit level, a limit of a certain number of repairs are allowed per integrated circuit; each array type has its own repair limit definition; multiple tests are assigned different priority levels by virtue of importance of, e.g., test, criticality of array (or other unit of circuits), criticality of integrated circuit level application, criticality of chiplet, recoverability of chiplet/application or a combination of one or more of above; optional repairability scheme of applying all, some or none of the repairs at a given priority level determined by if individual array repair limit was reached; must fix repairs (also referred to as critical repairs) of tests assigned the highest priority, with ability to reject a chip if the individual array repair limit is exceeded; must fix repairs (also referred to as critical repairs) of tests assigned the highest priority with the ability to reject an integrated circuit if the integrated circuit level repair limit is reached; and/or ability to trade off non-critical chiplet repairs for more repairs on a critical chiplet and downgrade the unrepaired chiplet (thus, still yielding the integrated circuit).

One or more aspects increase the accuracy of repairing the most critical/edge fails on an integrated circuit even with limits on available repairs, repair storage capacity, etc. One or more aspects increase yield.

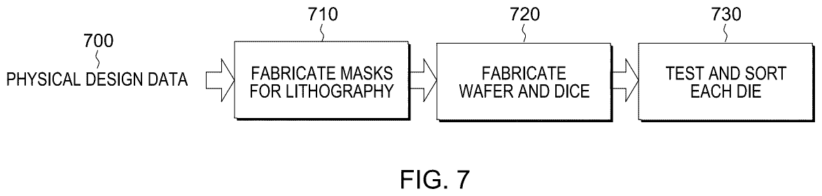

As noted, one or more aspects are related to testing and/or repairing integrated circuits, including individual circuits and/or units of circuits. One example of fabricating an integrated circuit is described with reference to FIGS. 7-9. FIG. 7 is one example of a flow diagram of a design process used in semiconductor design, manufacture, and/or test. In one example, based on obtaining physical design data 700, an integrated circuit is designed in accordance therewith and is fabricated, in one example, according to known processes that are generally described with reference to FIG. 7. Generally, a wafer with multiple copies of the final design is fabricated and cut (i.e., diced) such that each die is one copy of the integrated circuit. At block 710, the processes include fabricating masks for lithography based on the finalized physical layout. At block 720, fabricating the wafer includes using the masks to perform photolithography and etching. Once the wafer is diced, testing and sorting each die is performed at 730 to filter out any faulty die. In one example, at least some of the testing may be performed in accordance with one or more of the test-repair prioritization aspects described herein.

Furthermore, referring to FIGS. 7-9, in one or more embodiments, at least one processor is operative to generate a design structure for the integrated circuit design in accordance with the VLSI (Very Large Scale Integration) design, and in at least some embodiments, the at least one processor is further operative to control integrated circuit manufacturing equipment to fabricate a physical integrated circuit in accordance with the design structure. Thus, the layout can be instantiated as a design structure, and the design structure can be provided to fabrication equipment to facilitate fabrication of a physical integrated circuit in accordance with the design structure.

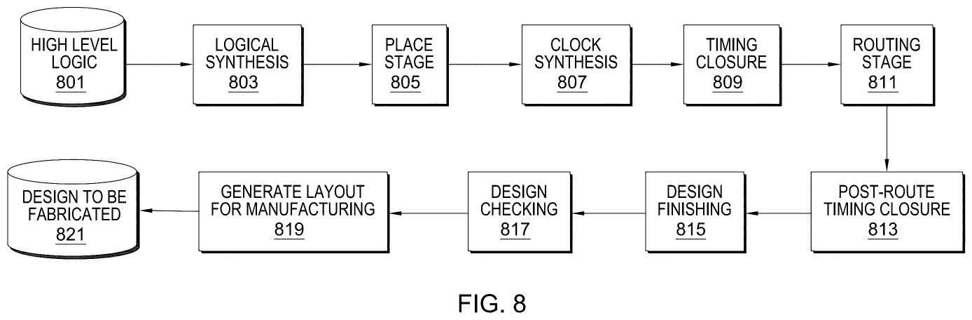

FIG. 8 depicts an example high-level Electronic Design Automation (EDA) tool flow, which is responsible for creating an optimized microprocessor (or other integrated circuit (IC)) design to be manufactured. A designer can start with a high-level logic description 801 of the circuit (e.g. VHDL (Very High Speed Integrated Circuit Hardware Description Language) or Verilog). The logic synthesis tool 803 compiles the logic and optimizes it without any sense of its physical representation, and with estimated timing information. A placement or place stage tool 805 takes the logical description and places each component, looking to minimize congestion in each area of the design. The clock synthesis tool 807 optimizes the clock tree network by cloning/balancing/buffering the latches or registers. The timing closure step 809 performs a number of optimizations on the design, including buffering, wire tuning, and circuit repowering; its goal is to produce a design which is routable, without timing violations, and without excess power consumption. Routing stage 811 takes the placed/optimized design and determines how to create wires to connect the components, without causing manufacturing violations. Post-route timing closure 813 performs another set of optimizations to resolve any violations that are remaining after the routing. Design finishing 815 then adds extra metal shapes to the netlist, to conform with manufacturing requirements. Design checking steps 817 analyze whether the design is violating any requirements such as manufacturing, timing, power, electromigration or noise. When the design is clean, the final step, generate layout for manufacturing 819, is to generate a layout for the design, representing all the shapes to be fabricated in the design to be fabricated 821.

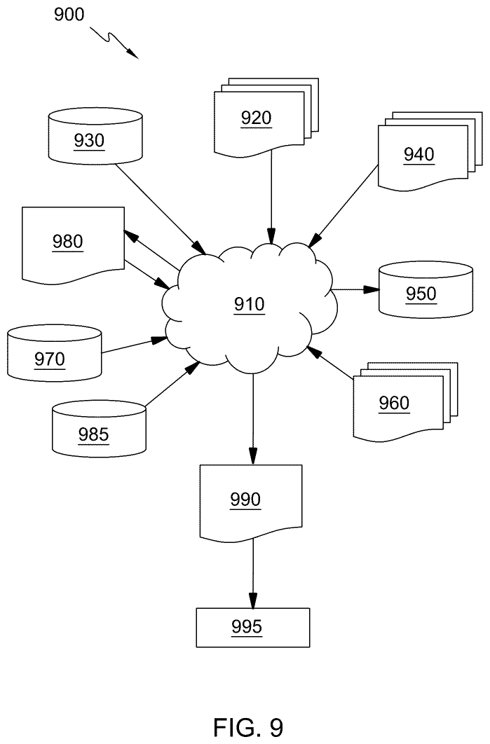

One or more embodiments integrate the timing and signal electromigration analysis techniques herein with semiconductor integrated circuit design simulation, test, layout, and/or manufacture. In this regard, FIG. 9 shows a block diagram of an example design flow 900 used for example, in semiconductor integrated circuit logic design, simulation, test, layout, and manufacture. Design flow 900 includes processes, machines and/or mechanisms for processing design structures or devices to generate logically or otherwise functionally equivalent representations of design structures and/or devices, such as those that can be analyzed using timing analysis or the like. The design structures processed and/or generated by design flow 900 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an integrated circuit design process, such as designing, manufacturing, or simulating a circuit, component, device, or system. For example, machines may include: lithography machines, machines and/or equipment for generating masks (e.g., E-V writers), computers, or equipment for simulating design structures, any apparatus used in the manufacturing or test process, or any machines for programming functionality equivalent representations of the design structures into any medium (e.g., a machine for programming a programmable gate array).

Design flow 900 may vary depending on the type of representation being designed. For example, a design flow 900 for building an application specific integrated circuit (ASIC) may differ from a design flow 900 for designing a standard component or from a design flow 900 for instantiating the design into a programmable array, for example a programmable gate array (PGA) or a field programmable gate array (FPGA).

FIG. 9 illustrates multiple such design structures 920 that is, for example, processed by a design process 910. Design structure 920 may be a logical simulation design structure generated and processed by design process 910 to produce a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD), such as implemented by a core developer/designer. When encoded on a gate array or storage medium, design structure 920 may be accessed and processed by one or more hardware and/or software modules within design process 910 to simulate or otherwise functionally represent an electronic component, circuit, electronic or logic module, apparatus, device, or system. As such, design structure 920 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages, such as Verilog and VHDL, and/or higher-level design languages, such as C or C++.

Design process 910, in one example, employs and incorporates hardware and/or software modules for synthesizing, translating, or otherwise processing a design/simulation functional equivalent of components, circuits, devices, or logic structures to generate a Netlist 980, which may contain design structures such as design structure 920. Netlist 980 may comprise, for example, compiled or otherwise processed data structures representing a list of wires, discrete components, logic gates, control circuits, I/O devices, modules, etc., that describes the connections to other elements and circuits in an integrated circuit design. Netlist 980 may be recorded on a machine-readable data storage medium or programmed into a programmable gate array, a compact flash, or other flash memory. Additionally, or in the alternative, the medium may be a system or cache memory, buffer space, or other suitable memory.

Design process 910 may include hardware and software modules for processing a variety of input data structure system, including Netlist 980. Such data structure types may reside, for example, within library elements 930 and include a set of commonly used elements, circuits, and devices, including models, layouts, and symbolic representations, for a given manufacturing technology (e.g., different technology nodes, 32 nm (nanometer), 45 nm, 90 nm, etc.). The data structure types may further include design specifications 940, characterization data 950, verification data 960, design rules 970, and test data files 985, which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910 without deviating from the scope and spirit of aspects of the disclosure. Design process 910 may also include modules for performing standard circuit design processes, such as timing analysis, verification, design rule checking, place and route operations, etc. Improved placement can be performed as described herein.

Design process 910 employs and incorporates logic and physical design tools, such as HDL compilers and simulation model build tools to process design structure 920 together with some or all of the depicted supporting data structures along with any additional mechanical design or data (if applicable), to generate a second design structure 990. Design structure 990 resides on a storage medium or programmable gate array in a data format used for the exchange of data of mechanical devices and structures (e.g. information stored in an IGES (Initial Graphics Exchange Specification), DXF (Drawing Exchange Format), Parasolid XT (Text Transmittal), JT (Jupiter Tessellation), DRG (Digital Raster Graphics), or any other suitable format for storing or rendering such mechanical design structures). Similar to design structure 920, design structure 990, in one example, comprises one or more files, data structures, or other computer-encoded data or instructions that reside on data storage media and that when processed by an ECAD (Electronic Computer-Aided Design) system generates a logically or otherwise functionally equivalent form of one or more integrated circuit designs or the like. In one embodiment, design structure 990 may comprise a compiled, executable HDL simulation model that functionally simulates the devices to be analyzed.

Design structure 990 may also employ a data format used for the exchange of layout data of integrated circuits and/or symbolic data format (e.g., information stored in a GDSII (Graphic Design System; GDS2) format, OASIS (Open Artwork System Exchange Standard) format, map files, or any other suitable format for storing such design data structures). Design structure 990 may comprise information such as, for example, symbolic data, map files, test data files, design content files, manufacturing data, layout parameters, wires, levels of metal, vias, shapes, data for routing through the manufacturing line, and any other data used by a manufacturer or other designer/developer to produce a device or structure as described herein (e.g., .lib files). Design structure 990 may then proceed to a stage 995 where, for example, design structure 990: proceeds to tape-out, is released to manufacturing, is released to a mask house, is sent to another design house, is sent back to the customer, etc.

In one or more examples, the integrated circuit being tested/repaired is of a computing environment that incorporates, performs and/or uses one or more aspects of the present disclosure. As examples, the computing environment may be of various architectures and of various types, including, but not limited to: personal computing, client-server, distributed, virtual, emulated, partitioned, non-partitioned, cloud-based, quantum, grid, time-sharing, cluster, peer-to-peer, wearable, mobile, having one node or multiple nodes, having one processor or multiple processors, and/or any other type of environment and/or configuration, etc. that is capable of executing a process (or multiple processes) that, e.g., performs testing and repairing of an integrated circuit and/or performs one or more other aspects of the present disclosure. Aspects of the present disclosure are not limited to a particular architecture or environment.

In one or more examples, the integrated circuit is part of the computing environment (e.g., a computing device (e.g., processor, computer, etc.) of the computing environment) and/or tested/repaired using code of the computing environment. For instance, the computing environment includes, as described herein, test-repair prioritization code to be used to perform selective testing and/or repairing, as described in one or more aspects herein. The test-repair prioritization code may be software, hardware and/or firmware. In one example, it performs the same functions as test-repair prioritization logic 70 and may be used to implement the processes described herein, including, but not limited to, those of FIGS. 5 and 6.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

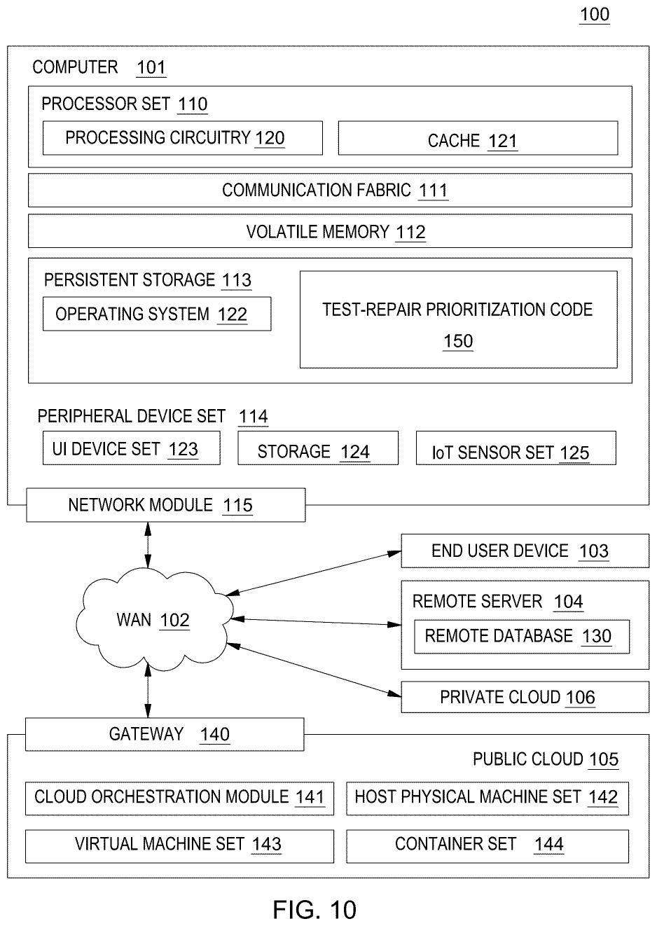

One example of a computing environment to perform, incorporate and/or use one or more aspects of the present disclosure is described with reference to FIG. 10. In one example, a computing environment 100 contains an example of an environment for the execution of at least some of the computer code involved in performing the inventive methods, such as test-repair prioritization code 150 (also referred to herein as block 150). In addition to construction block 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 10. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

Communication fabric 111 is the signal conduction paths that allow the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Cloud computing services and/or microservices (not separately shown in FIG. 10): private and public clouds 106, 105 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on-demand, and virtual private networks.

The computing environment described above is only one example of a computing environment to incorporate, perform and/or use one or more aspects of the present disclosure. Other examples are possible. For instance, in one or more embodiments, one or more of the components/modules/blocks of FIG. 10 are not included in the computing environment and/or are not used for one or more aspects of the present disclosure. Further, in one or more embodiments, additional and/or other components/modules/blocks may be used. Other variations are possible.

In one example, the test-repair prioritization code (e.g., test-repair prioritization code 150) is, e.g., computer-readable program code (e.g., instructions) in computer-readable media, e.g., storage (persistent storage 113, cache 121, storage 124, other storage, as examples). Although, as an example, test-repair prioritization code 150 is depicted in FIG. 10 in persistent storage 113, test-repair prioritization code and/or one or more portions of the test-repair prioritization code may be in other storage, such as storage 124, etc. Further, as described herein, test-repair prioritization code 150 and/or portions thereof may be implemented within the integrated circuit itself. Many variations are possible.

The computer-readable media may be part of one or more computer program products and the computer-readable program code may be executed by and/or using one or more computing devices (e.g., one or more computers, such as computer(s) 101; one or more servers, such as remote server(s) 104; one or more end user devices, such as end user device(s) 103; one or more processors or nodes, such as processor(s) or node(s) of processor set 110; processing circuitry, such as processing circuitry 120 of processor set 110; and/or other computing devices, etc.). Additional and/or other computers, servers, end user devices, processors, nodes, processing circuitry and/or other computing devices may be used to execute the test-repair prioritization code and/or portions thereof. Many examples are possible.

In one example, machine learning may be applied to facilitate one or more aspects of the present disclosure. For example, machine learning may be used to determine priorities, select units of circuits to be tested and/or develop tests/repairs, etc. The machine learning process continues to learn based on results and/or feedback. The learning is applied to retrain the machine learning models to further improve the models. Many examples are possible.

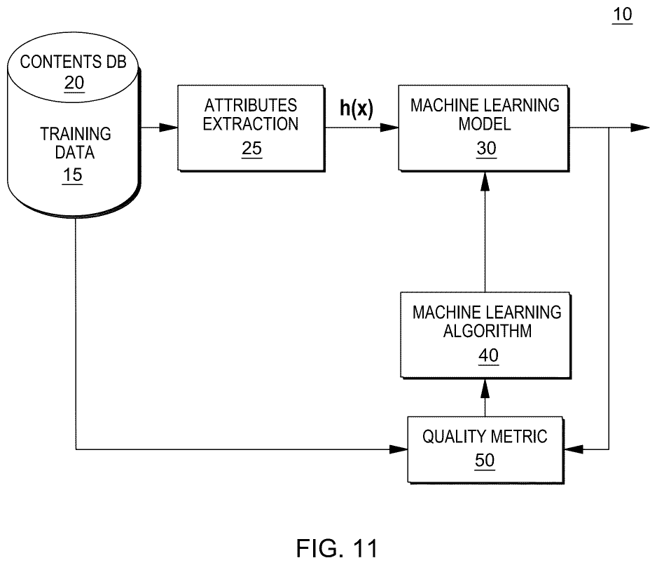

One example of a machine learning training system is described with reference to FIG. 11. In one or more aspects, a machine learning training system 10 may be utilized to perform cognitive analyses of various inputs, including input data, data from one or more sources (e.g., exogenous sources and/or other sources), repositories, data structures, and/or other data. Training data 15 utilized to train the model in one or more embodiments of the present disclosure includes, for instance, data that pertains to one or more events (e.g., tests, repairs, priorities and/or other events), such as natural language processing data; data being processed; data that pertains to conversations; data obtained from exogenous sources; data pertaining to data structures; data pertaining to artificial intelligence tasks; data pertaining to the occurrence of events and/or actions that have been taken; and/or available resources; etc. The program code in embodiments of the present disclosure performs a cognitive analysis to generate one or more training data structures, including algorithms utilized by the program code to predict states of a given event. Machine learning (ML) solves problems that are not solved with numerical means alone. In this ML-based example, program code extracts various attributes from ML training data 15 (e.g., historical data collected from various data sources relevant to the event, which may be resident in one or more databases 20 comprising event or other data. Training attributes 25 are utilized to develop a predictor function, h(x), also referred to as a hypothesis, which the program code utilizes as a machine learning model 30.

In identifying various event states, features, attribute similarities, constraints and/or behaviors indicative of states in the ML training data 15, the program code can utilize various techniques to identify training attributes in an embodiment of the present disclosure. Embodiments of the present disclosure utilize varying techniques to select training attributes (data attributes, elements, patterns, features, constraints, distribution, etc.), including but not limited to, diffusion mapping, principal component analysis, recursive feature elimination (a brute force approach to selecting training attributes), and/or a Random Forest, to select the training attributes related to various events. The program code may utilize a machine learning algorithm 40 to train the machine learning model 30 (e.g., the algorithms utilized by the program code), including providing weights for the conclusions, so that the program code can train the predictor functions that comprise the machine learning model 30. The conclusions may be evaluated by a quality metric 50. By selecting a diverse set of ML training data 15, the program code trains the machine learning model 30 to identify and weight various training attributes (e.g., data attributes, features, patterns, constraints, distributions, etc.) that correlate to various states of an event.

The model generated by the program code is self-learning as the program code updates the model based on active event feedback, as well as from the feedback received from data related to the event. For example, when the program code determines that there is a constraint, event, action, test, repair, priority, similarity or pattern (e.g., data attribute, record attribute similarity, query pattern, data distribution, search terms distribution, etc.) that was not previously predicted by the model, the program code utilizes a learning agent to update the model to reflect the state of the event, in order to improve predictions in the future. Additionally, when the program code determines that a prediction is incorrect, either based on receiving user feedback through an interface or based on monitoring related to the event, the program code updates the model to reflect the inaccuracy of the prediction for the given period of time. Program code comprising a learning agent cognitively analyzes the data deviating from the modeled expectations and adjusts the model to increase the accuracy of the model, moving forward.

In one or more embodiments, program code, executing on one or more processors, utilizes a cognitive analysis tool or agent (now known or later developed) to tune the model, based on data obtained from one or more data sources. In one or more embodiments, the program code interfaces with application programming interfaces to perform a cognitive analysis of obtained data. Specifically, in one or more embodiments, certain application programming interfaces comprise a cognitive agent (e.g., learning agent) that includes one or more programs, including, but not limited to, natural language classifiers, a retrieve and rank service that can surface the most relevant information from a collection of documents, concepts/visual insights, trade off analytics, document conversion, and/or relationship extraction. In an embodiment, one or more programs analyze the data obtained by the program code across various sources utilizing one or more of a natural language classifier, retrieve and rank application programming interfaces, and trade off analytics application programming interfaces. An application programming interface can also provide audio related application programming interface services, in the event that the collected data includes audio, which can be utilized by the program code, including but not limited to natural language processing, text to speech capabilities, and/or translation.

In one or more embodiments, the program code utilizes a neural network to analyze event-related data to generate the model utilized to predict the state of a given event at a given time. Neural networks are biologically-inspired programming paradigms, which enable a computer to learn and solve artificial intelligence problems. This learning is referred to as deep learning, which is a subset of machine learning, an aspect of artificial intelligence, and includes a set of techniques for learning in neural networks. Neural networks, including modular neural networks, are capable of pattern recognition with speed, accuracy, and efficiency, in situations where data sets are multiple and expansive, including across a distributed network, including but not limited to, cloud computing systems. Modern neural networks are non-linear statistical data modeling tools. They are usually used to model complex relationships between inputs and outputs or to identify patterns (or similarities) in data (i.e., neural networks are non-linear statistical data modeling or decision-making tools). In general, program code utilizing neural networks can model complex relationships between inputs and outputs and identify patterns in data. Because of the speed and efficiency of neural networks, especially when parsing multiple complex data sets, neural networks and deep learning provide solutions to many problems in multiple source processing, which the program code in one or more embodiments accomplishes when obtaining data and generating a model for predicting states of a given event.

One or more aspects of the present disclosure are tied to computer technology and facilitate processing within a computer, improving performance thereof. For instance, integrated circuits are tested and repaired such that performance is improved. In one example, as many repairs as possible can be made to be able to continue using a unit of circuits. In one or more examples, memory yield is improved. Many examples are possible.

In one or more aspects, repair prioritization is utilized in which different applications, tests, chiplets, recoverability, yield, etc. can be used to determine selectively which memory element(s) get repaired. Many examples are possible.

Methods, integrated circuits, systems and/or computer program products for performing one or more aspects of the present disclosure are described and/or claimed herein. In one or more further aspects, a method (integrated circuit, system and/or computer program product) of testing a chip that includes one or more arrays having redundant elements in the array(s) is provided. In one or more aspects:
Set a repair limit of a certain number of repairs allowed per chip, in which each array type has its own repair limit definition;
Selectively perform multiple tests at different priority levels assigned by virtue of importance of test, criticality of array, criticality of chip level application, criticality of chiplet, recoverability of chiplet/application or a combination of the above, using redundant elements in arrays, thereby guaranteeing not to run out of repairs in most chips, and thus increase yield;
Optionally, repairability scheme of applying all, some or none of the repairs at a given priority level determined by if an individual array repair limit was reached;
Fix repairs of tests assigned the highest priority, with ability to reject a chip if the individual array repair limit was exceeded or if the chip level repair limit is reached; and
System has the ability to trade off non-critical chiplet repairs for more repairs on a critical chiplet and downgrade the un-repaired chiplet (thus, still yielding the chip).

Other aspects, variations and/or embodiments are possible.

In addition to the above, one or more aspects may be provided, offered, deployed, managed, serviced, etc. by a service provider who offers management of customer environments. For instance, the service provider can create, maintain, support, etc. computer code and/or a computer infrastructure that performs one or more aspects for one or more customers. In return, the service provider may receive payment from the customer under a subscription and/or fee agreement, as examples. Additionally, or alternatively, the service provider may receive payment from the sale of advertising content to one or more third parties.

In one aspect, an application may be deployed for performing one or more embodiments. As one example, the deploying of an application comprises providing computer infrastructure operable to perform one or more embodiments.

As a further aspect, a computing infrastructure may be deployed comprising integrating computer-readable code into a computing system, in which the code in combination with the computing system is capable of performing one or more embodiments.

Yet as a further aspect, a process for integrating computing infrastructure comprising integrating computer-readable code into a computer system may be provided. The computer system comprises a computer-readable medium, in which the computer-readable medium comprises one or more embodiments. The code in combination with the computer system is capable of performing one or more embodiments.

Although various embodiments are described above, these are only examples. For example, other priorities and/or architectural limits may be used. Further, units of circuits other than memory arrays may be repaired and/or benefit from one or more aspects of the present disclosure. Many variations are possible.

Various aspects and embodiments are described herein. Further, many variations are possible without departing from a spirit of aspects of the present disclosure. It should be noted that, unless otherwise inconsistent, each aspect or feature described and/or claimed herein, and variants thereof, may be combinable with any other aspect or feature.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components and/or groups thereof.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A method comprising:
repairing an integrated circuit, the repairing including:
selecting a set of test-repairs of a plurality of sets of test-repairs generated to test the integrated circuit, the plurality of sets of test-repairs being assigned one or more priorities based on one or more predefined criteria related to the integrated circuit, and wherein the selecting is based on a chosen priority of the one or more priorities, wherein the set of test-repairs selected has the chosen priority;
executing one or more tests of the set of test-repairs on the integrated circuit and determining a number of repairs of the set of test-repairs to be performed on the integrated circuit, based on the executing of the one or more tests of the set of test-repairs;
evaluating whether the number of repairs to be performed is outside one or more architectural limits assigned to the integrated circuit; and
performing processing to perform selective repairs on the integrated circuit based on the evaluating indicating that the number of repairs is outside the one or more architectural limits assigned to the integrated circuit.

2. The method of claim 1, wherein the integrated circuit includes one or more units of circuits, the chosen priority is a highest priority compared to other priorities of the one or more priorities, and the performing processing includes downgrading one unit of circuits of the one or more units of circuits, wherein based on there being more than the one unit of circuits, one or more repairs are to be applied to at least one other unit of circuits of the one or more units of circuits, the one or more repairs being at least part of the selective repairs.

3. The method of claim 2, wherein the performing processing includes applying at least one repair, but less than all repairs, of the number of repairs to the one unit of circuits, the at least one repair being of the set of test-repairs and part of the selective repairs.

4. The method of claim 3, further comprising repeating, at least, the selecting, the executing and the evaluating one or more times for one or more other chosen priorities of the one or more priorities.

5. The method of claim 2, wherein the one unit of circuits comprises a memory array.

6. The method of claim 1, wherein the integrated circuit includes a plurality of units of circuits, the chosen priority is a lower priority compared to a highest priority of the one or more priorities, and the performing processing includes bypassing repairs of one unit of circuits of the plurality of units of circuits to repair other units of circuits of the plurality of units of circuits.

7. The method of claim 1, further comprising applying the number of repairs based on the evaluating indicating that the number of repairs is within the one or more architectural limits assigned to the integrated circuit.

8. The method of claim 7, further comprising repeating, at least, the selecting, the executing and the evaluating one or more times for one or more other chosen priorities of the one or more priorities.

9. The method of claim 1, wherein the one or more architectural limits include an integrated circuit repair limit assigned to the integrated circuit.

10. The method of claim 1, wherein the integrated circuit includes a plurality of units of circuits, and wherein the one or more architectural limits include one or more repair limits assigned to the plurality of units of circuits.

11. An integrated circuit comprising:
logic to perform operations including:
repairing an integrated circuit, the repairing including:
selecting a set of test-repairs of a plurality of sets of test-repairs generated to test the integrated circuit, the plurality of sets of test-repairs being assigned one or more priorities based on one or more predefined criteria related to the integrated circuit, and wherein the selecting is based on a chosen priority of the one or more priorities, wherein the set of test-repairs selected has the chosen priority;
executing one or more tests of the set of test-repairs on the integrated circuit and determining a number of repairs of the set of test-repairs to be performed on the integrated circuit, based on the executing of the one or more tests of the set of test-repairs;
evaluating whether the number of repairs to be performed is outside one or more architectural limits assigned to the integrated circuit; and
performing processing to perform selective repairs on the integrated circuit based on the evaluating indicating that the number of repairs is outside the one or more architectural limits assigned to the integrated circuit.

12. The integrated circuit of claim 11, wherein the integrated circuit includes one or more units of circuits, the chosen priority is a highest priority compared to other priorities of the one or more priorities, and the performing processing includes downgrading one unit of circuits of the one or more units of circuits, wherein based on there being more than the one unit of circuits, one or more repairs are to be applied to at least one other unit of circuits of the one or more units of circuits, the one or more repairs being at least part of the selective repairs.

13. The integrated circuit of claim 12, wherein the performing processing includes applying at least one repair, but less than all repairs, of the number of repairs to the one unit of circuits, the at least one repair being of the set of test-repairs and part of the selective repairs.

14. The integrated circuit of claim 11, wherein the integrated circuit includes a plurality of units of circuits, the chosen priority is a lower priority compared to a highest priority of the one or more priorities, and the performing processing includes bypassing repairs of one unit of circuits of the plurality of units of circuits to repair other units of circuits of the plurality of units of circuits.

15. The integrated circuit of claim 11, wherein the operations further comprise applying the number of repairs based on the evaluating indicating that the number of repairs is within the one or more architectural limits assigned to the integrated circuit.

16. A computer program product comprising:
a set of one or more computer-readable storage media; and
program instructions, collectively stored in the set of one or more computer-readable storage media, for causing at least one computing device of a computing environment to perform computer operations including:
repairing an integrated circuit, the repairing including:
selecting a set of test-repairs of a plurality of sets of test-repairs generated to test the integrated circuit, the plurality of sets of test-repairs being assigned one or more priorities based on one or more predefined criteria related to the integrated circuit, and wherein the selecting is based on a chosen priority of the one or more priorities, wherein the set of test-repairs selected has the chosen priority;
executing one or more tests of the set of test-repairs on the integrated circuit and determining a number of repairs of the set of test-repairs to be performed on the integrated circuit, based on the executing of the one or more tests of the set of test-repairs;
evaluating whether the number of repairs to be performed is outside one or more architectural limits assigned to the integrated circuit; and
performing processing to perform selective repairs on the integrated circuit based on the evaluating indicating that the number of repairs is outside the one or more architectural limits assigned to the integrated circuit.

17. The computer program product of claim 16, wherein the integrated circuit includes one or more units of circuits, the chosen priority is a highest priority compared to other priorities of the one or more priorities, and the performing processing includes downgrading one unit of circuits of the one or more units of circuits, wherein based on there being more than the one unit of circuits, one or more repairs are to be applied to at least one other unit of circuits of the one or more units of circuits, the one or more repairs being at least part of the selective repairs.

18. The computer program product of claim 17, wherein the performing processing includes applying at least one repair, but less than all repairs, of the number of repairs to the one unit of circuits, the at least one repair being of the set of test-repairs and included in the selective repairs.

19. The computer program product of claim 16, wherein the integrated circuit includes a plurality of units of circuits, the chosen priority is a lower priority compared to a highest priority of the one or more priorities, and the performing processing includes bypassing repairs of one unit of circuits of the plurality of units of circuits to repair other units of circuits of the plurality of units of circuits.

20. The computer program product of claim 16, wherein the operations further comprise applying the number of repairs based on the evaluating indicating that the number of repairs is within the one or more architectural limits assigned to the integrated circuit.

21. A computer system comprising:
a set of computing devices of a computing environment;
a set of one or more computer-readable storage media; and
program instructions, collectively stored in the set of one or more computer-readable storage media, for causing at least one computing device of the set of computing devices to perform computer operations including:
repairing an integrated circuit, the repairing including:
selecting a set of test-repairs of a plurality of sets of test-repairs generated to test the integrated circuit, the plurality of sets of test-repairs being assigned one or more priorities based on one or more predefined criteria related to the integrated circuit, and wherein the selecting is based on a chosen priority of the one or more priorities, wherein the set of test-repairs selected has the chosen priority;
executing one or more tests of the set of test-repairs on the integrated circuit and determining a number of repairs of the set of test-repairs to be performed on the integrated circuit, based on the executing of the one or more tests of the set of test-repairs;
evaluating whether the number of repairs to be performed is outside one or more architectural limits assigned to the integrated circuit; and
performing processing to perform selective repairs on the integrated circuit based on the evaluating indicating that the number of repairs is outside the one or more architectural limits assigned to the integrated circuit.

22. The computer system of claim 21, wherein the integrated circuit includes one or more units of circuits, the chosen priority is a highest priority compared to other priorities of the one or more priorities, and the performing processing includes downgrading one unit of circuits of the one or more units of circuits, wherein based on there being more than the one unit of circuits, one or more repairs are to be applied to at least one other unit of circuits of the one or more units of circuits, the one or more repairs being at least part of the selective repairs.

23. The computer system of claim 21, wherein the integrated circuit includes a plurality of units of circuits, the chosen priority is a lower priority compared to a highest priority of the one or more priorities, and the performing processing includes bypassing repairs of one unit of circuits of the plurality of units of circuits to repair other units of circuits of the plurality of units of circuits.

24. A method comprising:
repairing an integrated circuit, the integrated circuit being assigned an integrated circuit repair limit and including a plurality of memory arrays, the plurality of memory arrays being assigned one or more array repair limits, the repairing including:
selecting a set of test-repairs of a plurality of sets of test-repairs generated to test the integrated circuit, the plurality of sets of test-repairs being assigned one or more priorities based on one or more predefined criteria related to the integrated circuit, and wherein the selecting is based on a chosen priority of the one or more priorities, wherein the set of test-repairs selected has the chosen priority;
executing one or more tests of the set of test-repairs on a memory array of the plurality of memory arrays of the integrated circuit and determining a number of repairs of the set of test-repairs to be performed on the memory array, based on the executing of the one or more tests of the set of test-repairs;
evaluating whether the number of repairs to be performed is outside an array repair limit assigned to the memory array;
evaluating whether the number of repairs to be performed is outside the integrated circuit repair limit assigned to the integrated circuit;
determining based on the number of repairs to be performed being outside the array repair limit and the integrated circuit repair limit whether the memory array is to be downgraded to a lower priority level compared to the priority level at which it was tested; and
downgrading the memory array to the lower priority level to continue repairing one or more other memory arrays of the plurality of memory arrays, based on the determining indicating that the memory array is to be downgraded, wherein the integrated circuit is still usable subsequent to the downgrading.

25. The method of claim 24, further comprising rejecting the integrated circuit based on the determining indicating that the memory array is not to be downgraded.
